(19) United States
(12) Patent Application Publication
(10) Pub. No.: US 2003/0006483 A1
(43) Pub. Date: Jan. 9, 2003

(54) Short channel power MOSFET with increased breakdown voltage

(75) Inventors: Kyle Spring, Temecula, CA (US); Jianjun Cao, Temecula, CA (US)

Correspondence Address: OSTROLENK FABER GERB & SOFFEN, 1180 AVENUE OF THE AMERICAS, NEW YORK, NY, 100368403

(73) Assignee: International Rectifier Corp.

(21) Appl. No.: 10/112,821

(22) Filed: Mar. 28, 2002

Related U.S. Application Data
(60) Provisional application No. 60/279,275, filed on Mar. 28, 2001.

(51) Int. Cl. H01L 29/80

(52) U.S. Cl. 257/563; 257/287; 257/341

(57) ABSTRACT

A MOSFET that includes short channel regions for a reduced R_{DSON}, and narrowly spaced, relatively deep base regions for an improved breakdown voltage.

### RELATED APPLICATIONS

This application claims priority to U.S. Provisional Application No. 60/279,275, filed on Mar. 28, 2001 the disclosure of which is hereby incorporated by reference.

### FIELD OF THE INVENTION

This invention relates to power MOSFETs and more specifically it relates to a process for the manufacture of a MOSFET which includes very short channels to reduce the on-resistance of the device without an adverse affect on the breakdown voltage.

### BACKGROUND OF THE INVENTION

Two of the desired properties of a MOSgated device, such as a MOSFET, are a high breakdown voltage and a low on-resistance (R_{DSON}). Breakdown voltage and the R_{DSON} are often competing properties in a MOSgated device meaning that to obtain a favorable value for one the other must be sacrificed. For example, a reduction in the value of R_{DSON} often leads to a reduction in the breakdown voltage.

The prior art structure shown in FIG. 1 achieves a lower R_{DSON} by using shallow base regions 16,18,20. When shallow base regions 16,18,20 are used, lateral diffusion is limited so that a greater number of cells or stripes can be packed into a given area. This increases the total channel width of a die and reduces R_{DSON}. However, when the channel junction is made more shallow, the curvature of the PN junction between base regions 16,18,20 and the junction receiving epitaxial layer 10 is sharper, thus leading to a reduced breakdown voltage.

In a vertical conduction MOSFET the source and the drain electrodes are separated by a region that has a conductivity opposite to that of the source and the drain electrodes. This region, which is referred to as a channel, is inverted to the same polarity as the source and the drain regions by application of an electric field to electrically connect the source and the drain electrodes. The source of the electric field used for inversion of the channel is an electrically isolated electrode, which is referred to as a gate electrode, which may be given a voltage with respect to the channel to create an electric field for causing the inversion of the channel. Once the channel is inverted, voltage between the source and the drain electrode leads to the conduction of current.

R_{DSON} of a MOSFET is the resistance between its drain and source electrodes during conduction. The length of the channel contributes to the value of R_{DSON} in a MOSFET. Typically, the longer the channel the higher the R_{DSON}. Therefore, one way R_{DSON} can be reduced is by reducing the length of the channel region of a MOSFET. However, reduction of the length of the channel may result in punch-through which is an undesirable condition. Punch-through occurs when a depletion region near a source electrode of the MOSFET expands to make contact with the source electrode thereby providing a current path between the source and the drain at the drain voltage thus causing a soft breakdown. A shorter channel often raises concerns for the possibility of punch-through.

It would be desirable to employ short channels to reduce R_{DSON} without reducing the breakdown voltage.

### BRIEF DESCRIPTION OF THE INVENTION

A MOSFET according to the present invention includes short channels for a reduced R_{DSON} and deep and closely spaced base regions to prevent the lowering of the breakdown voltage of the device. In accordance with the invention, a short channel MOSFET is made using a narrower polysilicon gate electrode than used by the prior art. This results in having base regions that are closer to one another than the prior art devices. The closeness of the base regions allows the junctions to pinch off near the surface of the MOSFET before the junction depletes back to the source, which in turn prevents punch-through, thus reducing the possibility of a soft breakdown. Moreover, a MOSFET according to the present invention includes deeper base regions. The deeper base regions provide for PN junctions having higher radii of curvature than the prior art devices, thus improving the breakdown capability of the MOSFET.

A MOSFET according to the present invention includes a junction receiving layer of a first conductivity type having a first concentration of impurities disposed atop a substrate of a first conductivity type having a concentration of impurities that is higher than the first concentration of impurities; a plurality of base regions of a second conductivity type spaced about 0.3 to 6 microns apart, the second conductivity type being opposite to that of said first conductivity type; a plurality of source regions, each source region being disposed in a respective base region and separated from the junction receiving layer by an invertible channel that is less than about 0.4 microns wide, wherein the base regions extend from a top free surface of said junction receiving layer to a depth of about 1.5 to 4.0 microns. A MOSFET according to the present invention further includes gate electrodes each having a width of about 2 to 6 microns.

A process according to the present invention also produces a MOSFET that can have a lower threshold voltage Vₜₕ than the prior art MOSFETs because the concentration of impurities in its channels are lower than the prior art device, specially near the surface of the junction receiving layer and under the gate electrodes.

### BRIEF DESCRIPTION OF THE DRAWINGS

FIG. 1 is a cross-section of a small portion of a MOSFET according to prior art.

FIG. 2 is a cross-section of a small portion of a MOSFET according to the present invention.

Other features and advantages of the present invention will become apparent from the following description of the invention which refers to the accompanying drawings.

### DETAILED DESCRIPTION OF THE DRAWINGS

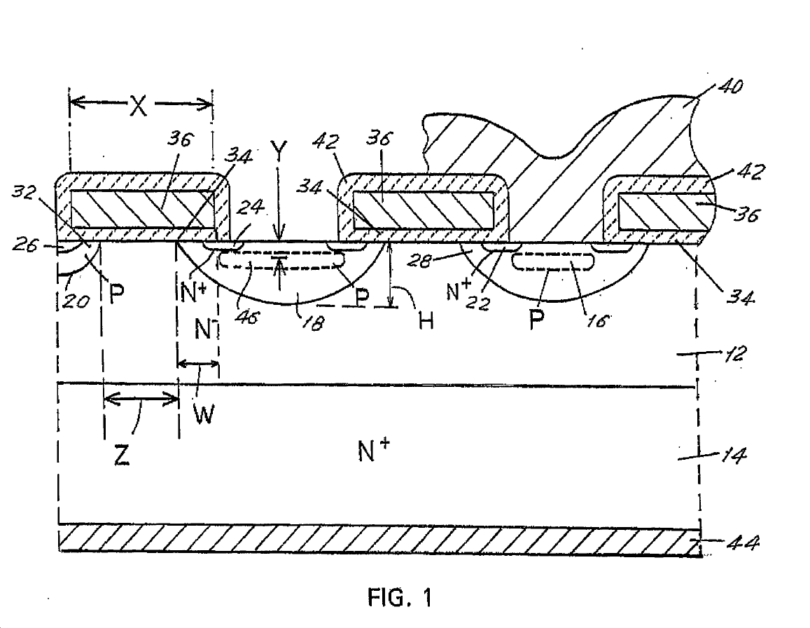

Referring to FIG. 1, MOSFET 10 according to the prior art includes a plurality of PN junctions formed in a junction receiving layer 12. Junction receiving layer 12 is an epitaxial layer grown on doped substrate 14 and is doped with impurities of the same conductivity as the impurities of doped substrate 14. Doped substrate 14 is typically made of silicon, but other materials can be used to form a substrate. The concentration of impurities in junction receiving layer 12 of MOSFET 10 is lower than that of doped substrate 14.

PN junctions are formed in the top surface of junction receiving layer 12 by implanting impurities of a conductivity type opposite to those in junction receiving layer 12 and doped substrate 14 to form base regions 16,18,20. Base regions 16,18,20 are spaced apart by a predetermined distance Z. In MOSFET 10 according to prior art distance Z is about 1 to 5 microns depending on the desired breakdown voltage. Each base region 16,18,20 includes at least one source region, e.g. 22,24,26, having impurities of the same conductivity type as junction receiving layer 12 and substrate 14. Source regions, e.g., 22,24,26, may be implanted in base regions 16,18,20, at a distance away from junction receiving layer 12 such that they are separated from junction receiving layer 12 by a channel region, e.g. 28,30,32. A layer of oxide 34 is disposed over each channel region, e.g., 28,30,32. Oxide layers 34 prevent gate electrodes 36 from making physical contact with channel regions, e.g., 28,30,32; however, when a voltage of sufficient value is applied to gate electrodes 36 an electric field permeates oxide layers 34 to invert channel regions, e.g., 28,30,32, thereby providing a current path between source regions, e.g., 22,24,26 and junction receiving layer 12.

MOSFET 10 includes source contact layer 40 in ohmic contact with source regions, e.g. 22. Source contact layer 40 is insulated from gate electrodes 36 by a low temperature oxide layer 42 which is disposed over gate electrodes 36.

MOSFET 10 also includes drain contact layer 44, which is disposed over a free surface of doped substrate 14 opposite to the surface on which junction receiving layer 12 is disposed. Source contact layer 40 and drain contact layer 44 are typically made from a highly conductive metal such as aluminum. When channel regions, e.g. 28,30,32 are inverted as described above, current may flow between source contact layer 40 and drain contact layer 44 under application of a voltage between these two contacts.

MOSFET 10 includes gate electrodes 36 that have a width X of about 4 to 8 microns and base regions 16,18, 20 each being about 1 to 3 microns deep. Base regions have depth H and extend beyond the edge of the polysilicon gate electrode 36 by a dimension W. The ratio of H/W in the prior art is about 1.25. This ratio is a constant, independent of the drive of base regions 16,18,20. When the drive of base regions 16,18,20 is reduced in order to shorten the channel, the radius of curvature is reduced, which leads to a lower breakdown voltage. MOSFET 10 according to the prior art may use a cellular or a stripe base structure. Whether a cellular base structure is used or a stripe base structure the cross-section of the device would be identical as that shown in FIG. 1.

In MOSFET 10 shown in FIG. 1 base regions 16,18,20 are doped with P-type dopants while epitaxially deposited junction receiving layer 12 is doped with N-type dopants. This arrangement provides for an N channel device because channel regions, e.g. 28,30,32 are inverted from P-type to N-type when an appropriate amount of voltage is applied to gate electrodes 36. The impurity types in each region can be reversed in each region to make a P channel device.

A typical process for forming MOSFET 10 first requires forming an epitaxial layer of silicon on an N-type silicon substrate 14. The epitaxial layer will serve as junction receiving layer 12 and will have a lower concentration of N-type impurities than that of N-type silicon substrate 14. Gate oxide layer 34 is grown atop the top surface of junction receiving layer 12 and a conductive polycrystalline gate electrode 36 is deposited atop layer 34. These layers are then photolithographically patterned and etched to define gate electrodes 36 with a width “X” of about 4 microns to about 8 microns. The etched pattern will define openings in gate oxide layer 34 and polysilicon gate electrode layer 36 to expose areas on top of junction receiving layer 12 that will be implanted with impurities to form base regions 16,18,20. The etched area will space gate electrodes 36 about 1 micron to 8 microns apart.

To form base regions 16,18,20 boron atoms are implanted injunction receiving layer 12 through the opening in gate oxide layer 34 and polysilicon gate electrode 36 using an implant energy of about 80 KeV and a dose of about 5E13 atoms/cm² to 1.5E14 atoms/cm², which results in a shallow layer of boron atoms 46 in junction, receiving layer 12, as shown by broken lines. Shallow layer of boron atoms 46 has a peak concentration of boron atoms. For a base structure known in the art, the depth “Y” of shallow layer of boron atoms is about 0.25 microns. Thereafter, the boron implant is subjected to a heat treatment at about 1175° C for about 60 minutes to drive the boron atoms to a depth of about 2.5 microns to form base regions 16,18,20. This drive also causes the lateral expansion of base regions under gate electrodes 36.

N+source regions, e.g. 22,24,26, are then formed by implanting As atoms with a dose of about 8E15 atoms/cm² and an energy of 120 KeV, again using polysilicon gate electrodes 36 and gate oxide 34 as a mask to define self aligned invertible channel regions, e.g. 28,30,32. Note that in MOSFET 10, the “JFET” or common conduction region has a width “Z” between spaced base regions 16,18,20 of about 1 to 5 microns depending on the desired breakdown voltage of the device.

MOSFET 10 is then completed by deposition of a low temperature oxide layer 42 such as TEOS over its upper surface and over the edges of polysilicon gate electrodes. Oxide is next removed to permit source contact 40 to make contact with base regions 16,18,20 and source regions, e.g. 22,24,26. Drain contact 44 can then be deposited on the free surface of doped silicon substrate 14 opposite to junction receiving layer 12.

the prior art device of claim 1, the use of a short channel of 0.4 microns or less, between the outer periphery of sources regions, e.g. 22,24,26, and the outer periphery of base regions 16,18,20, respectively, normally leads to a low breakdown voltage because the depth H of base regions 16,18,20 is small, because the shallow junction has a relatively small radius of curvature, and because of the punch-through phenomenon. The present invention avoid these problems by changing the structure of MOSFET 10 to improve the breakdown characteristics of the device while employing a short channel to reduce R_{DSON}.

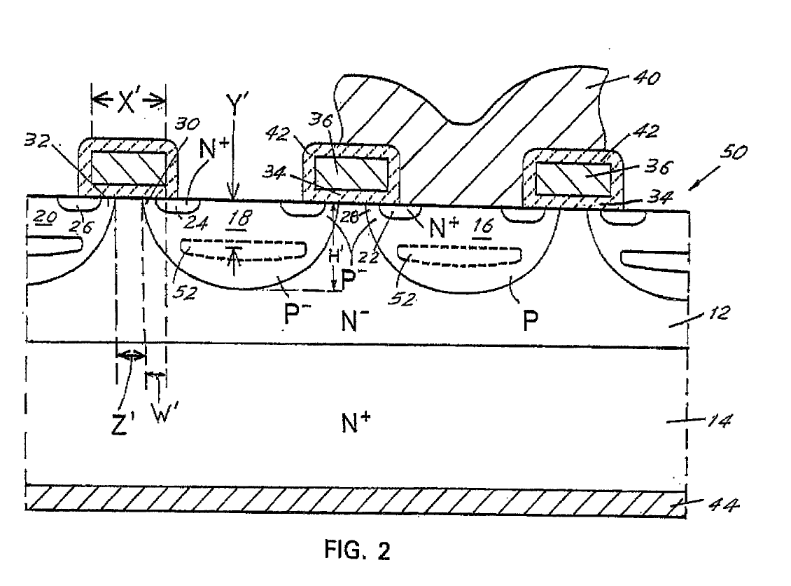

FIG. 2 shows a cross-section of MOSFET 50 according to the present invention in which like numerals identify like features in MOSFET 10. MOSFET 50 overcomes the disadvantageous characteristics of MOSFET 10 of prior art.

MOSFET 50 uses a reduced width X′ gate electrode 36 of about 2 to 6 microns instead of a width of about 4 to 8 microns. This reduces the space “Z′” between base regions 16,18,20 to about 0.3 to 4 microns instead of about 1 to 5 microns. A second change requires increased ratio of H′/W′. This is accomplished by increasing the implant energy of boron atoms from about 80 KeV to 120 KeV up to about 2 MeV whereby boron atoms are implanted to a depth “Y′” of about 0.4 microns to 3 microns. The region 52 at depth of about 0.4 microns to 3 microns is the location of the peak concentration of boron atoms. These implanted boron atoms are then diffused at about 1125° C for 30 minutes which results in base regions 16,18,20 that are about 1.5 to 4.0 microns deep. Thus, as a result of this process deeper base regions can be obtained with a lateral diffusion under gate electrodes 36 that is shorter and thus more suitable for formation of shorter channels.

An alternative process is to implant a low boron dose of 1E12 to 1E13 atoms/cm² at 150 KeV to 300 KeV to a depth of about 0.4 to 0.6 microns, followed by a drive at about 1175° C. for 1 to 2 hours. A second boron implant of 5E13 to 1.5E14 atoms/cm² is performed at 80 KeV to 150 KeV, followed by a drive at about 1125° C. for about 30 minutes, which results in base regions 16,18,20 that are about 2.5 microns deep.

The high energy implantation of boron atoms results in having a peak concentration at a deeper location. As a result, base regions 16,18,20 are reshaped, increasing the ratio of H′/W′ and their radii of curvature, thus improving the breakdown voltage. Also the narrower width X′ of gate electrodes 36 permits the junctions to pinch off near the surface of the silicon before the junction depletes back to the source, thus preventing punch through and further improving the breakdown voltage. Using this configuration a short channel width of about 0.4 microns can be used in MOSFET 50 to improve the R_{DSON} of the MOSFET 50 without having a concern for the lower breakdown voltage which may be caused by punch-through.

Further, advantageously, MOSFET 50 can have a lower threshold voltage Vth because, due to deeper implantation of boron ions, the P-type impurity concentration in channel regions, e.g. 28,30,32, under gate electrodes 36 is reduced in value.

As an example, Table 1 shows two 75V N-channel MOSFET devices one according to prior art and the other according to the present invention.

TABLE 1

| | | | | | | | Specific |
|---|---|---|---|---|---|---|---|
| | | | | | | | On- |
| | | Channel | | | | | resistance |
| | | Implant | | | Channel | | R_{DSON}* AA |
| Parameters | X | Energy | Y | | Drive | H/W | (mΩ-mm² |
| Prior Art | 5.8 microns | 80 KeV | 0.25 | microns | 1125° C./90′ | about 1.25 | 130 |
| Present | 5.0 microns | 150 KeV | 0.4 | microns | 1125° C./30′ | about 1.8 | 105 |
| Invention | | | | | | | |

Although the present invention has been described in relation to particular embodiments thereof, many other variations and modifications and other uses will become apparent to those skilled in the art. It is preferred, therefore, that the present invention be limited not by the specific disclosure herein.

What is claimed is:

1. A process for making a power MOSgated device having a short channel and a high breakdown voltage comprising:
growing an epitaxial layer of a first conductivity type and a first concentration on a substrate having impurities of said first conductivity type and a higher concentration of impurities than said first concentration;
growing a gate oxide layer atop said epitaxial layer;
growing a polysilicon gate electrode layer atop said gate oxide layer;
etching said gate oxide layer and said polysilicon gate electrode to create a plurality of about 2 to about 6 micron wide portions of polysilicon gate electrode atop corresponding gate oxide portions, said portions being spaced apart;
forming a plurality of body regions of a second conductivity type opposing to said first conductivity type in said epitaxial layer between said spaced polysilicon gate electrode and said gate oxide portions, said body regions being spaced about 0.3 to about 4 microns apart and extending from a top surface of said epitaxial layer to a predetermined depth; and
forming source regions of said first conductivity type in each said body region, each said source region being isolated from said epitaxial layer by an invertible channel in said body region, said channel being about 0.4 microns or less.

2. A process for making a power MOSgated device according to claim 1, wherein a metallic contact layer is formed on a surface of said substrate opposing said epitaxial layer.

3. A process for making a power MOSgated device according to claim 1, wherein a low temperature insulating layer is formed over said polysilicon gate electrode and said gate oxide portions, and a metallic contact layer is formed said low temperature insulating layer and in contact with said source regions.

4. A process for making a power MOSgated device according to claim 1, wherein said body regions are formed by implanting impurities of said second conductivity type using an implant energy of about 120 KeV to about 2 MeV whereby said impurities of said second conductivity type are implanted to a depth of about 0.4 to about 3 microns, and then diffusing said impurities of said second conductivity type at about 1125 C. for about 30 minutes.

5. A process of making a power MOSgated device according to claim 4, wherein said impurities of said second conductivity type are boron atoms.

6. A process for making a power MOSgated device according to claim 1, wherein said body regions are formed by first implanting a first dose of impurities of said second conductivity type using an implant energy of about 150 KeV to about 300 KeV to a depth of about 0.4 to about 0.6 microns followed by a diffusion drive at about 1175 C for about 1 to about 2 hours, and then implanting a second dose of impurities of said second conductivity type at about 80 KeV to about 150 KeV followed by a diffusion drive at about 1125 C. for about 30 minutes.

7. A process for making a power MOSgated device according to claim 6, wherein said impurities of said second conductivity type are boron atoms, said first dose is about 1E12 to about 1E13, and said second dose is about 5E13 to about 1.5E14.

8. A process for making a power MOSgated device according to claim 1, wherein said impurities of said first conductivity type are As atoms and impurities of said second conductivity type are boron atoms.

9. A process for making a power MOSgated device according to claim 1, wherein said substrate comprises of a silicon crystal.

10. A process for making a power MOSgated device according to claim 1, wherein said epitaxial layer comprises of silicon.

11. A process for making a power MOSgated device according to claim 1, wherein said base regions are one of cellular and stripe configuration.

12. A MOSgated device comprising:
a junction receiving layer of a first conductivity type of a first concentration of impurities disposed atop a substrate of a first conductivity type having a concentration of impurities that is higher than the first concentration of impurities;
a plurality of base regions of a second conductivity type spaced about 0.3 to 4 microns apart, said second conductivity type being opposite to that of said first conductivity type; and
a plurality of source regions each disposed in a respective base region and separated from said junction receiving layer by an invertible channel that is about 0.4 microns or less wide.

13. The MOSgated device of claim 12 wherein said base regions extend from a top free surface of said junction receiving layer to a depth of about 1.5 to 4.0 microns.

14. The MOSgated device of claim 12 further comprising gate electrodes each having a width of about 2 to 6 microns.

15. The MOSgated device of claim 12 further comprising a first metallic contact layer in contact with said source regions, and a second metallic contact layer in contact with a free surface of said doped substrate opposing said junction receiving layer.

16. A MOSgated device according to claim 12, wherein a ratio of the maximum depth of at least one of said base regions and a portion of said at lease one base region that is disposed between an edge of said base region and an edge of an adjacently disposed polysilicon gate electrode is more than 1.25.
